(19) United States
(12) Patent Application Publication
(10) Pub. No.: US 2018/0006662 A1
(43) Pub. Date: Jan. 4, 2018

(54) BIT-ERROR RATE FALSE POSITIVE DETECTION SYSTEM AND METHOD

(71) Applicant: Intel IP Corporation, Santa Clara, CA (US)

(72) Inventors: Gwang-Hyun Gho, Cupertino, CA (US); Matthew Hayes, Radebeul (DE)

(21) Appl. No.: 15/201,402

(22) Filed: Jul. 2, 2016

(51) Int. Cl. H03M 13/09; H03M 13/00

(52) U.S. Cl. CPC H03M 13/098; H03M 13/611

(57) ABSTRACT

A communication device can be configured to detect false positives of a decoded signal that have passed error detection. The communication device can include an error detector and a false positive detector. The error detector can detect an error of a decoded signal generated from an encoded signal, and output a payload of the decoded signal in response to the decoded signal passing the error detection. The false positive detector can calculate an estimated bit-error rate (BER) of the encoded signal and a predicted BER of the encoded signal. The false positive detector can determine a false positive of the error detection passing of the decoded signal based on the estimated BER and the predicted BER.

### BACKGROUND

### Field

Aspects described herein generally relate to error detection and correction of communication signals, including detection and/or reduction of false positives in the detection of errors (e.g., bit errors) of the communications signals.

### BRIEF DESCRIPTION OF THE DRAWINGS/FIGURES

The accompanying drawings, which are incorporated herein and form a part of the specification, illustrate the aspects of the present disclosure and, together with the description, further serve to explain the principles of the aspects and to enable a person skilled in the pertinent art to make and use the aspects.

FIG. 1 illustrates an example network environment.

FIG. 2 illustrates a base station according to an exemplary aspect of the present disclosure.

FIG. 3 illustrates a mobile device according to an exemplary aspect of the present disclosure.

FIG. 4 illustrates a mobile device according to an exemplary aspect of the present disclosure.

FIGS. 5A-5B illustrate a false positive detection method according to an exemplary aspect of the present disclosure.

FIG. 6 illustrates a plot of the predicted bit-error rate of a signal according to an exemplary aspect of the present disclosure.

The exemplary aspects of the present disclosure will be described with reference to the accompanying drawings. The drawing in which an element first appears is typically indicated by the leftmost digit(s) in the corresponding reference number.

### DETAILED DESCRIPTION

In the following description, numerous specific details are set forth in order to provide a thorough understanding of the aspects of the present disclosure. However, it will be apparent to those skilled in the art that the aspects, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring aspects of the disclosure.

In the following disclosure, references to the Long-Term Evolution (LTE) standard are made. However, the more generic terms “mobile device” and “base station” are used herein except where otherwise noted to refer to the LTE terms “User Equipment (UE)” and “eNodeB/eNB,” respectively.

As an overview, in LTE, the Physical Downlink Control Channel (PDCCH) carries Downlink Control Information (DCI) that contains scheduling assignments for various downlink and uplink channels and other control information. The PDCCH is transmitted in the control symbol region of a subframe. In one or more exemplary aspects, the PDCCH payload is protected by error control codes, such as cyclic-redundancy check (CRC) code for error detection. The PDCCH payload can be followed by tail-biting convolutional code (TBCC) for error correction. In exemplary aspects, the mobile device can be configured to perform one or more blind decodes to detect the mobile device's own DCIs out of multiple DCIs for multiple UEs that are multiplexed into the common control region.

In operation, in error control systems (e.g., CRC-protected error control systems), the PDCCH can experience false positives—where erroneously corrected information bits by forward error correction (FEC) still passes CRC check.

In exemplary aspects of the present disclosure, system and methods for detecting false positive (FP) are described. In one or more exemplary aspects, the FP detection can be based on one or more threshold parameters. The threshold parameter(s) can be dynamically adjusted based on one or more channel condition and system configuration. In exemplary aspects, the detection and reduction of false positives can improve the performance of control channel (e.g., LTE control channel) reception by reducing the mobile device and/or a corresponding base station from entering one or more erroneous states of downlink (DL) and/or uplink (UL) protocols.

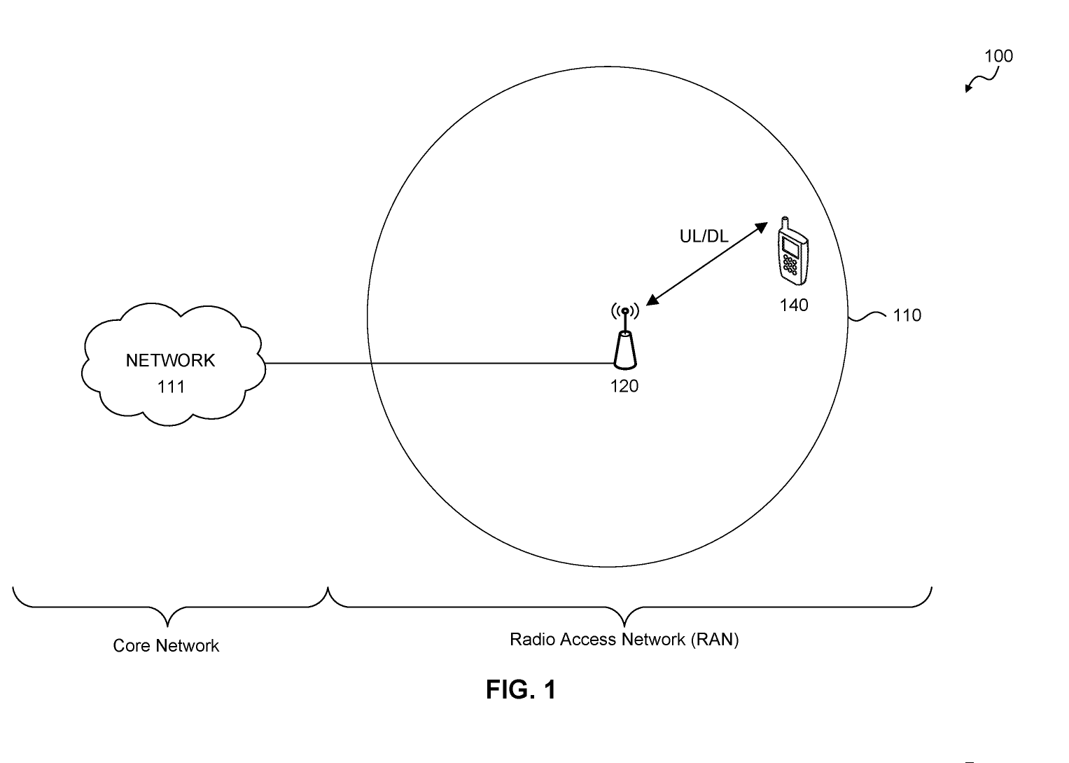

FIG. 1 illustrates an example communication environment 100 that includes a radio access network (RAN) and a core network. The RAN includes one or more base stations 120 and one or more mobile devices 140. The core network includes a backhaul communication network 111. In an exemplary aspect, the backhaul communication network 111 can include one or more well-known communication components—such as one or more network switches, one or more network gateways, and/or one or more servers. The backhaul communication network 111 can include one or more devices and/or components configured to exchange data with one or more other devices and/or components via one or more wired and/or wireless communications protocols. In exemplary aspects, the base stations 120 communicate with one or more service providers and/or one or more other base stations 120 via the backhaul communication network 111. In an exemplary aspect, the backhaul communication network is an internet protocol (IP) backhaul network. The number of base stations 120, mobile devices 140, and/or networks 111 are not limited to the quantities illustrated in FIG. 1, and the communication environment 100 can include any number of the various components as would be understood by one of ordinary skill in the relevant art(s).

The mobile device 140 and the base station 120 can each include a transceiver configured to transmit and/or receive wireless communications via one or more wireless technologies within the communication environment 100. In operation, the mobile device 140 can be configured to communicate with the base station 120 in a serving cell or sector 110 of the communication environment 100. For example, the mobile device 140 receives signals on one or more downlink (DL) channels from the base station 120, and transmits signals to the base station 120 on one or more respective uplink (UL) channels.

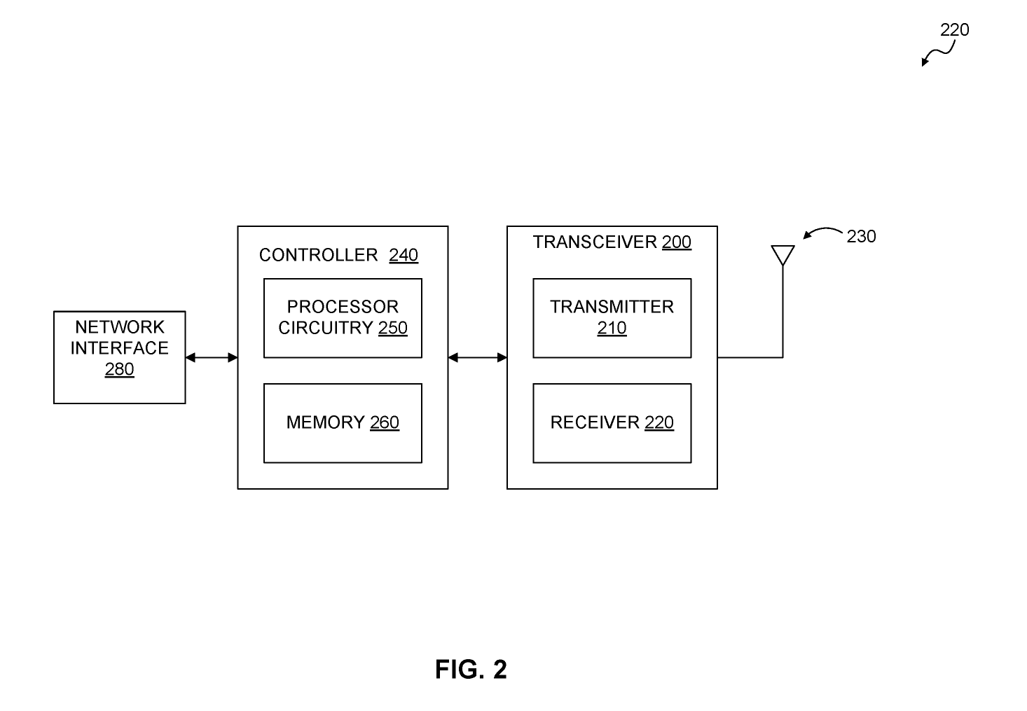

FIG. 2 illustrates the base station 220 according to an exemplary aspect of the present disclosure. The base station 220 can be an exemplary aspect of the base station 120. The base station 220 can include a transceiver 200 and a network interface 280, each communicatively coupled to controller 240.

The transceiver 200 includes processor circuitry that is configured to transmit and/or receive wireless communications via one or more wireless technologies within the communication environment 100. For example, the transceiver 200 can include one or more transmitters 210 and one or more receivers 220 that configured to transmit and receive wireless communications, respectively, via one or more antennas 230. Those skilled in the relevant art(s) will recognize that the transceiver 200 can also include (but is not limited to) a digital signal processer (DSP), modulator and/or demodulator, a digital-to-analog converter (DAC) and/or an analog-to-digital converter (ADC), and/or a frequency converter (including mixers, local oscillators, and filters) to provide some examples. Further, those skilled in the relevant art(s) will recognize that the antenna 230 may include an integer array of antennas, and that the antenna 230 may be capable of both transmitting and receiving wireless communication signals. For example, the base station 120 can be configured for wireless communication utilizing a Multiple-input Multiple-output (MIMO) configuration.

In an exemplary aspect, the transceiver 200 is configured for wireless communications conforming to, for example, the Long-Term Evolution (LTE) protocol. In this example, the transceiver 200 can be referred to as LTE transceiver 200. Those skilled in the relevant art(s) will understand that the transceiver 200 is not limited to LTE communications, and can be configured for communications that conform to one or more other protocols.

The network interface 280 includes processor circuitry that is configured to transmit and/or receive communications via one or more wired technologies to/from the backhaul communication network 111. Those skilled in the relevant art(s) will recognize that the network interface 280 can also include (but is not limited to) a digital signal processer (DSP), modulator and/or demodulator, a digital-to-analog converter (DAC) and/or an analog-to-digital converter (ADC), and/or a frequency converter (including mixers, local oscillators, and filters) to provide some examples. Further, those skilled in the relevant art(s) will understand that the network interface 280 is not limited to wired communication technologies and can be configured for communications that conform to one or more well-known wireless technologies in addition to, or alternatively to, one or more well-known wired technologies.

The controller 240 can include processor circuitry 250 that is configured to carry out instructions to perform arithmetical, logical, and/or input/output (I/O) operations of the base station 120 and/or one or more components of the base station 120. The processor circuitry 250 can be configured control the operation of the transceiver 200—including, for example, transmitting and/or receiving of wireless communications via the transceiver 200, and/or perform one or more baseband processing functions (e.g., media access control (MAC), encoding/decoding, modulation/demodulation, data symbol mapping, error correction, etc.).

The controller 240 can further include a memory 260 that stores data and/or instructions, where when the instructions are executed by the processor circuitry 250, controls the processor circuitry 250 to perform the functions described herein. The memory 260 can be any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory 260 can be non-removable, removable, or a combination of both.

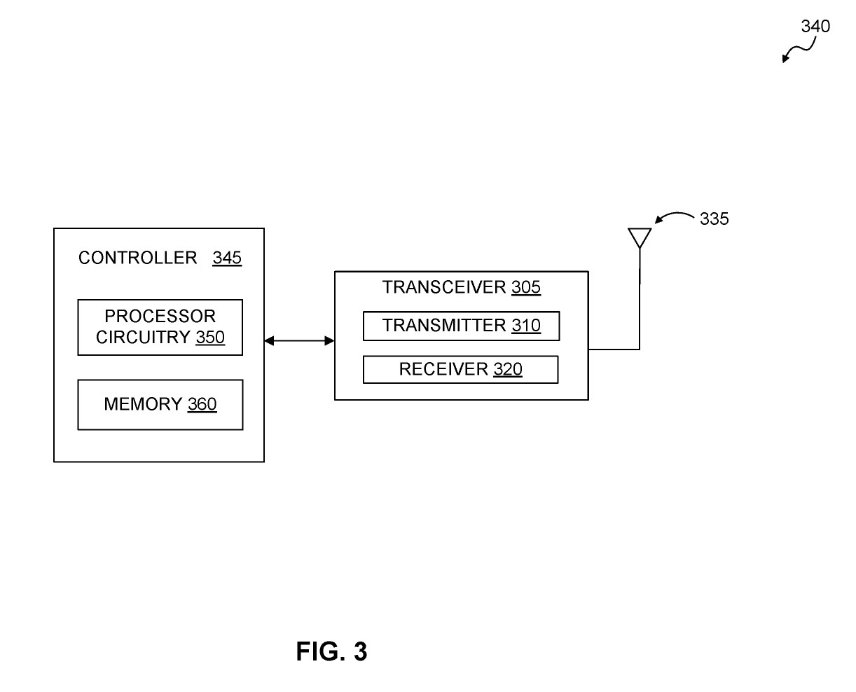

FIG. 3 illustrates a mobile device 340 according to an exemplary aspect of the present disclosure. The mobile device 340 can be an exemplary aspect of the mobile device 140. The mobile device 340 is configured to transmit and/or receive wireless communications via one or more wireless technologies. For example, the mobile device 340 can be configured for wireless communications conforming to, for example, the Long-Term Evolution (LTE) protocol, but is not limited thereto.

The mobile device 340 can be configured to communicate with one or more other communication devices, including, for example, one or more base stations, one or more access points, one or more other mobile devices, and/or one or more other devices as would be understood by one of ordinary skill in the relevant arts.

The mobile device 340 can include a controller 345 communicatively coupled to one or more transceivers 305. The transceiver(s) 305 can be configured to transmit and/or receive wireless communications via one or more wireless technologies. The transceiver 305 can include processor circuitry that is configured for transmitting and/or receiving wireless communications conforming to one or more wireless protocols. For example, the transceiver 305 can include a transmitter 310 and a receiver 320 configured for transmitting and receiving wireless communications, respectively, via one or more antennas 335.

In exemplary aspects, the transceiver 305 can include (but is not limited to) a digital signal processer (DSP), modulator and/or demodulator, a digital-to-analog converter (DAC) and/or an analog-to-digital converter (ADC), an encoder/decoder (e.g., encoders/decoders having convolution, tail-biting convolution, turbo, Viterbi, and/or Low Density Parity Check (LDPC) encoder/decoder functionality), a frequency converter (including mixers, local oscillators, and filters), Fast-Fourier Transform (FFT), precoder, and/or constellation mapper/de-mapper that can be utilized in transmitting and/or receiving of wireless communications. Further, those skilled in the relevant art(s) will recognize that antenna 335 may include an integer array of antennas, and that the antennas may be capable of both transmitting and receiving wireless communication signals. In aspects having two or more transceivers 305, the two or more transceivers 305 can have their own antenna 335, or can share a common antenna via a duplexer.

The controller 345 can include processor circuitry 350 that is configured to control the overall operation of the mobile device 340, such as the operation of the transceiver(s) 305. The processor circuitry 350 can be configured to control the transmitting and/or receiving of wireless communications via the transceiver(s) 305, and/or perform one or more baseband processing functions (e.g., media access control (MAC), encoding/decoding, modulation/demodulation, data symbol mapping; error correction, etc.). The processor circuitry 350 can be configured to run one or more applications and/or operating systems; power management (e.g., battery control and monitoring); display settings; volume control; and/or user interactions via one or more user interfaces (e.g., keyboard, touchscreen display, microphone, speaker, etc.). In an exemplary aspect, the controller 345 can include one or more elements of a protocol stack such as, a physical (PHY) layer, media access control (MAC), radio link control (RLC), packet data convergence protocol (PDCP), and/or radio resource control (RRC) elements.

The controller 345 can further include a memory 360 that stores data and/or instructions, where when the instructions are executed by the processor circuitry 350, controls the processor circuitry 350 to perform the functions described herein. The memory 360 can be any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory 360 can be non-removable, removable, or a combination of both.

Examples of the mobile device 340 include (but are not limited to) a mobile computing device—such as a laptop computer, a tablet computer, a mobile telephone or smartphone, a “phablet,” a personal digital assistant (PDA), and mobile media player; and a wearable computing device—such as a computerized wrist watch or “smart” watch, and computerized eyeglasses. In some aspects of the present disclosure, the mobile device 340 may be a stationary communication device, including, for example, a stationary computing device—such as a personal computer (PC), a desktop computer, a computerized kiosk, and an automotive/aeronautical/maritime in-dash computer terminal.

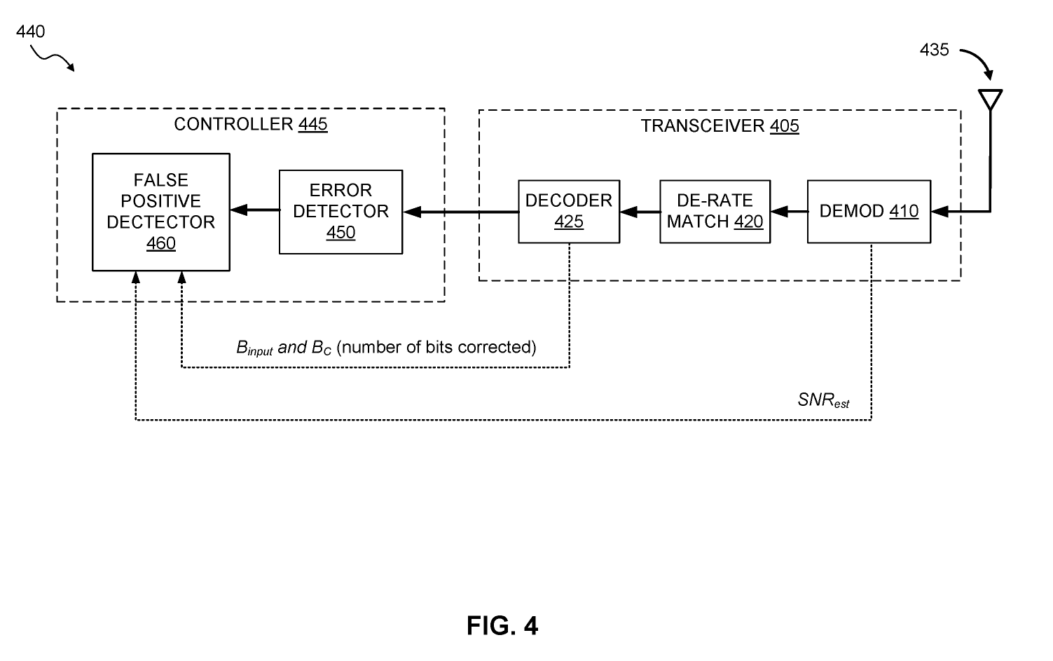

FIG. 4 illustrates a mobile device 440 according to an exemplary aspect of the present disclosure. The mobile device 440 can be an exemplary aspect of the mobile device 340 and/or 140. The mobile device 440 is configured to transmit and/or receive wireless communications via one or more wireless technologies. For example, the mobile device 440 can be configured for wireless communications conforming to, for example, the LTE protocol, but is not limited thereto.

In an exemplary aspect, the mobile device 440 is configured to detect false positives of communication signals that have passed error detection. For example, a communication signal can be decoded, and checked for errors using one or more error detection methodologies (e.g., cyclic redundancy check (CRC)). The error detection methodology will determine whether the communication signal has been decoded successfully (e.g., is error free). In some situations, which is referred herein as a “false positive (FP),” the communication signal can successfully pass the error detection processing even though the decoded communication signal contains one or more errors and/or was not successfully (i.e., completely) repaired using, for example, parity information.

In an exemplary aspect, the mobile device 440 includes a transceiver 405 and a controller 445. The transceiver 405 can be an exemplary aspect of the transceiver 305. The controller 445 can be an exemplary aspect of the controller 345.

In an exemplary aspect, the transceiver 405 can include a demodulator 410, a de-rate matching circuit 420, and a decoder 425. The controller 445 can include an error detector 450 and a false positive detector 460. In an exemplary aspect, the error detector 450 and a false positive detector 460 are implemented in the processor circuitry 350 of the controller 345.

In an exemplary aspect, the demodulator 410 is configured to receive one or more radio frequency (RF) signals via the antenna 435, and to demodulate the RF signal(s) to generate one or more demodulated signals. The demodulated signals can be one or more baseband signals corresponding to the RF signal(s). In an exemplary aspect, the demodulator 410 can include a mixer and an oscillator (not shown), where the mixer receives the RF signal(s) and mixes the RF signal(s) with one or more received oscillating signals generated by the oscillator to generate the demodulated signal(s). In an exemplary aspect, the demodulator 410 includes processor circuitry configured to perform one or more functions and/or operations of the demodulator 410, such as demodulating the RF signal(s).

The de-rate matching circuit 420 can be configured to perform one or more de-rate matching operations on the demodulated signal to remove rate matching that may have been applied to the received signal by, for example, the transmitting device (e.g., base station). For example, the de-rate matching circuit 420 can be configured to perform one or more de-rate matching operations on the demodulated signal to remove rate matching based on a repetition factor. In an exemplary aspect, the de-rate matching circuit 420 includes processor circuitry configured to perform one or more functions and/or operations of the de-rate matching circuit 420, such as one or more de-rate matching operations.

In an exemplary aspect, the de-rate matching circuit 420 is configured to perform one or more de-rate matching operations on the demodulated signal to generate a de-rate matched signal S_{drm} that satisfies the following equation:

$${S}_{drm} ( i ) = \{ \begin{matrix}{\sum }_{j = 0}^{Z} {S}_{demod} ( i + jX ) , & i = 0 , … , ( W - 1 ) \\ {\sum }_{j = 0}^{Z - 1} {S}_{demand} ( i + jX ) , & i = W , … , ( X - 1 )\end{matrix}$$

where S_{demod} is the demodulated signal, X=dciLenth×E, Y=F_{allocation}×L,

$${F}_{repetition} = \frac{( {F}_{allocation} \times L )}{( dciLength \times E )} , and$$

$$Z = ⌊ {F}_{repetition} ⌋ = ⌊ \frac{( {F}_{allocation} \times L )}{( dciLength \times E )} ⌋ = ⌊ \frac{Y}{X} ⌋ ,$$

where W=Y−(X×Z). F_{allocation} is an allocation factor that corresponds to a minimum unit of bits of for allocation of the communication protocol. For example, the F_{allocation}=72 for PDCCH allocation. L is the aggregation level of minimum unit in the range {1, 2, 4, 8}, dciLength is the payload size of the received communication signal including error detecting code (e.g., cyclic redundancy check (CRC) bits), and E is the encoding factor at which the received communication signal was encoded by, for example, the transmitting device (e.g., base station). In an exemplary aspect, the encoder of the transmitting device is a rate (1/3) convolutional encoder and therefore the encoder factor E is 3. In an exemplary aspect, the demodulated signal generated by the demodulator 410 has a bit length of F_{allocation}×L, and the de-rate matched signal S_{drm} has a bit length of dciLength×E.

The decoder 425 can be configured to decode one or more coded signals to generate one or more corresponding decoded signals. The decoder 425 can be configured to output the decoded signal to the controller 445 (e.g., error detector 450 of the controller 445). In an exemplary aspect, the decoding operations of the decoder 425 can correct one or more bits of the input de-rate matched signal.

In operation, decoder 425 can be configured to receive a signal from the de-rate matching circuit 420 (e.g., de-rate matched signal S_{drm}) and decode the received signal to generate a decoded signal. In an exemplary aspect, the decoder 425 includes processor circuitry configured to perform one or more functions and/or operations of the decoder 425, such as decoding one or more coded signals. In an exemplary aspect where the demodulated signal generated by the demodulator 410 has a bit length of F_{allocation}×L, and the de-rate matched signal S_{drm} has a bit length of dciLength×E, the decoded signal generated by the decoder 425 will have a bit length of dciLength (e.g., the payload plus error detecting code).

In an exemplary aspect, the decoder 425 is a Viterbi decoder configured to use a Viterbi algorithm for decoding a bitstream that has been encoded using, for example, convolutional code or trellis code. The decoder 425 is not limited to a Viterbi decoder and can be another decoder type as would be understood by one of ordinary skill in the relevant arts. Further, the decoding algorithm implemented by the decoder 425 to perform decoding is not limited and can be any decoding algorithm as would be understood by one or ordinary skill in the relevant arts.

The error detector 450 can be configured to perform one or more error detection operations to detect one or more errors of a received signal. In an exemplary aspect, error detector 450 can be configured to detect one or more errors of the received signal based on an error detection code, such as a cyclic redundancy check (CRC) code. In an exemplary aspect, the error detector 450 includes processor circuitry configured to perform one or more functions and/or operations of the error detector 450, such as one or more error detection operations.

For example, the error detector 450 can detect one or more bit errors of the decoded signal received from the decoder 425. The error detector 450 can be configured to use one or more error detection methodologies and/or algorithms to detect errors. In an exemplary aspect, the error detector 450 can be configured to use cyclic redundancy check (CRC) code, but is not limited thereto.

In operation, the error detector 450 can be configured to check the integrity/validity of the payload bits of the received signal based on the error detection code bits (e.g., the CRC code). The error detector 450 can generate an output that includes the payload data and/or a value indicative of whether the payload data is valid. The output of the error detector 450 can be provided to the false positive detector 460.

The false positive detector 460 can be configured to detect one or more false positives of the signals received from the error detector 450 that have been passed error detection (i.e., determined to have valid payloads by the error detector 450). For example, the decoded signal having been checked for errors by the error detector 450 and determined to be error free by the error detector 450 may nonetheless contain errors. This scenario of a “passing” determination of a signal that nonetheless contains errors is referred herein as a false positive error check or a false positive (FP). That is, the error detection methodology used by the error detector 450 will determine whether the decoded signal has been decoded successfully (e.g., is error free) by the decoder 425. In some situations (i.e., false positives), the decoded signal successfully passes the error detection processing of the error detector 450 even though the decoded signal contains one or more errors. In an exemplary aspect, the false positive detector 460 includes processor circuitry configured to perform one or more functions and/or operations of the false positive detector 450, such as one or more false positive detection operations.

In an exemplary aspect, the false positive detector 460 can be configured calculate a predicted bit-error rate (BER) (P_{b,pred}) and an estimated BER (P_{b,est}), and determine an occurrence of a false positive based on the predicted BER and the estimated BER.

The false positive detector 460 can be configured calculate the predicted BER (P_{b,pred}) based on a signal-to-noise ratio (SNR) of the RF signal received by the transceiver 405. In this example, the demodulator 410 can be configured to estimate the SNR and provide the estimated SNR to the false positive detector 460. The demodulator 410 can be configured to estimate the SNR based on one or more pilot and/or reference signals within the received RF signal.

In an exemplary aspect, the false positive detector 450 can be configured calculate the predicted BER (P_{b,pred}) based on the following equation:

P_{b,pred}=Q(\sqrt{SNRₑₛₜ×F_{allocation}×L/(dciLenth×E)})

where Q(•) refers to the Q function, SNRₑₛₜ is the estimated SNR of the signal, F_{allocation} is the allocation factor that corresponds to a minimum unit of bits of for allocation of the communication protocol (e.g., F_{allocation}=72 for PDCCH allocation), L is the aggregation level of minimum unit in range of {1,2,4,8}, dciLength is the payload size of the received communication signal including error detecting code (e.g., CRC bits), and E is the encoding factor at which the received communication signal was encoded (e.g., E=3). In an exemplary aspect, the calculation the predicted BER (P_{b,pred}) assumes that the communication channel is an additive white Gaussian noise (AWGN) channel and the received RF signal has been modulated using Quadrature phase-shift keying (QPSK).

In an exemplary aspect, the false positive detector 460 can be configured calculate the predicted BER (P_{b,pred}) based on a SNR margin factor (SNR_{margin}) that can be used to adjust the sensitivity of the predicted BER. The calculation of the predicted BER (P_{b,pred}) based on the SNR margin factor (SNR_{margin}) can satisfy the following equation:

$${P}_{b , pred} = Q ( \sqrt{( {SNR}_{est} - {SNR}_{margin} ) \times {F}_{allocation} \times L / ( dciLenth \times E} )$$

where SNR_{margin} is the SNR margin factor. The SNR margin factor can be predetermined or dynamically adjusted based on one or more characteristics of the communication channel, including, for example, the SNR and/or fading statistics.

In calculating the predicted BER (P_{b,pred}) based on a SNR margin factor (SNR_{margin}), the value of the predicted BER (P_{b,pred}) can be adjusted so as to increase or decrease the likelihood of a false positive determination as described in detail below.

The false positive detector 460 can be configured calculate the estimated BER (P_{b,est}) based on the number of bits corrected (B_{C}) by the decoder 425 and the number of input bits (Bᵢₙₚᵤₜ) (i.e., bits of the coded signal) of the decoder 425. In this example, the decoder 425 can be configured to provide the number of bits corrected (B_{C}) and/or the number of input bits (Bᵢₙₚᵤₜ) to the false positive detector 460. In an alternative aspect, the decoder 425 can be configured calculate the estimated BER based on the number of bits corrected (B_{C}) and the number of input bits (Bᵢₙₚᵤₜ), and provide the estimated BER to the false positive detector 460.

In an exemplary aspect, the false positive detector 460 can be configured calculate the estimated BER (P_{b,est}) based on a ratio of the number of bits corrected (B_{C}) and the number of input bits (Bᵢₙₚᵤₜ). For example, the estimated BER (P_{b,est}) can be calculated based on the following equation:

$${P}_{b , est} = \frac{{B}_{C}}{{B}_{input}} = \frac{{B}_{C}}{( dciLenth \times E )}$$

where B_{C} is the number of bits corrected by the decoder 425, Bᵢₙₚᵤₜ is the number of input bits of the decoder 425, dciLength is the payload size of the received communication signal including error detecting code (e.g., CRC bits), and E is the encoding factor at which the received communication signal was encoded (e.g., E=3).

In an exemplary aspect, the false positive detector 460 calculate an occurrence of a false positive (FP) based on the predicted BER (P_{b,pred}) and the estimated BER (P_{b,est}) so as to satisfy the following equation:

$$FP = \{ \begin{matrix}YES , & {P}_{b , est} > {P}_{b , pred} \\ NO , & {P}_{b , est} \leq {P}_{b , pred}\end{matrix}$$

In this example, if the estimated BER (P_{b,est}) is greater than the predicted BER (P_{b,pred}), the false positive detector 460 determines that a false positive (FP) has occurred. Otherwise, the false positive detector 460 determines that a false positive (FP) has not occurred.

In an exemplary aspect where the predicted BER (P_{b,pred}) is calculated based on the SNR margin factor (SNR_{margin}) a smaller value of the SNR margin factor (SNR_{margin}) results in a greater value of the predicted BER (P_{b,pred}), thereby reducing the likelihood that the false positive detector 460 determines that a false positive (FP) has occurred.

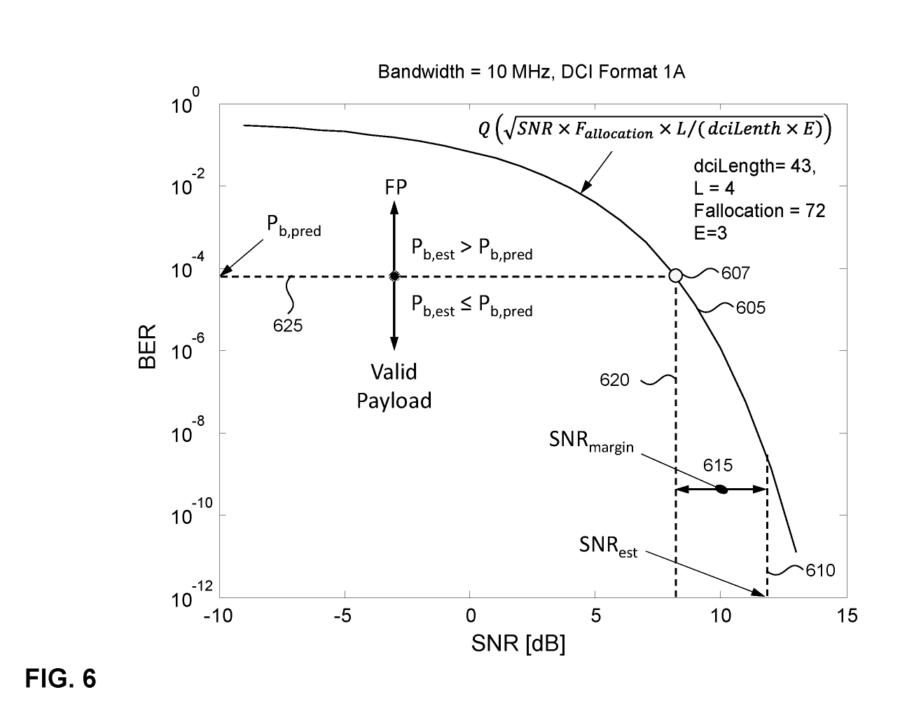

FIG. 6 illustrates a plot of the predicted BER (P_{b,pred}) of a signal with respect to the SNR of the signal according to an exemplary aspect of the present disclosure. In this example, the predicted BER (P_{b,pred}) is shown as line 605. A SNR value 620 can be determined based on the estimated SNR of the signal (SNRₑₛₜ) 610 and the signal SNR margin factor (SNR_{margin}) 615. A BER (P_{b,pred}) value 625 can be determined based on the SNR value 620. For example, the BER (P_{b,pred}) value along the predicted BER (P_{b,pred}) plot 605 at point 607 corresponds to the BER (P_{b,pred}) value at the SNR value 620. By comparing the BER (P_{b,pred}) value 625 to the estimated BER (P_{b,est}), it can be determined if the payload is valid or corresponds to a false positive. For example, if the estimated BER (P_{b,est}) is greater than the predicted BER (P_{b,pred}) value 625, a false positive (FP) has occurred. Otherwise (e.g., when the estimated BER (P_{b,est}) is less than the predicted BER (P_{b,pred}) value 625), a false positive (FP) has not occurred and the payload of the signal is valid. In the plot illustrated in FIG. 6, the bandwidth of the signal is 10 Mhz and the DCI format is 1A. Further, the dciLength=43, L=4, F_{allocation}=72 and E=3. These values are not to be limited and the signal characteristics and parameters can be different as would be understood by one of ordinary skill in the relevant arts.

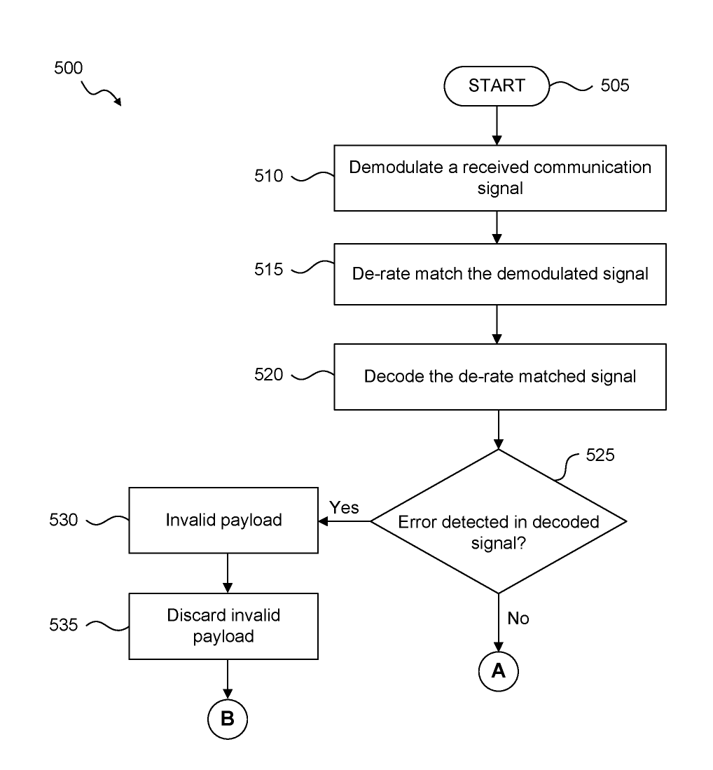

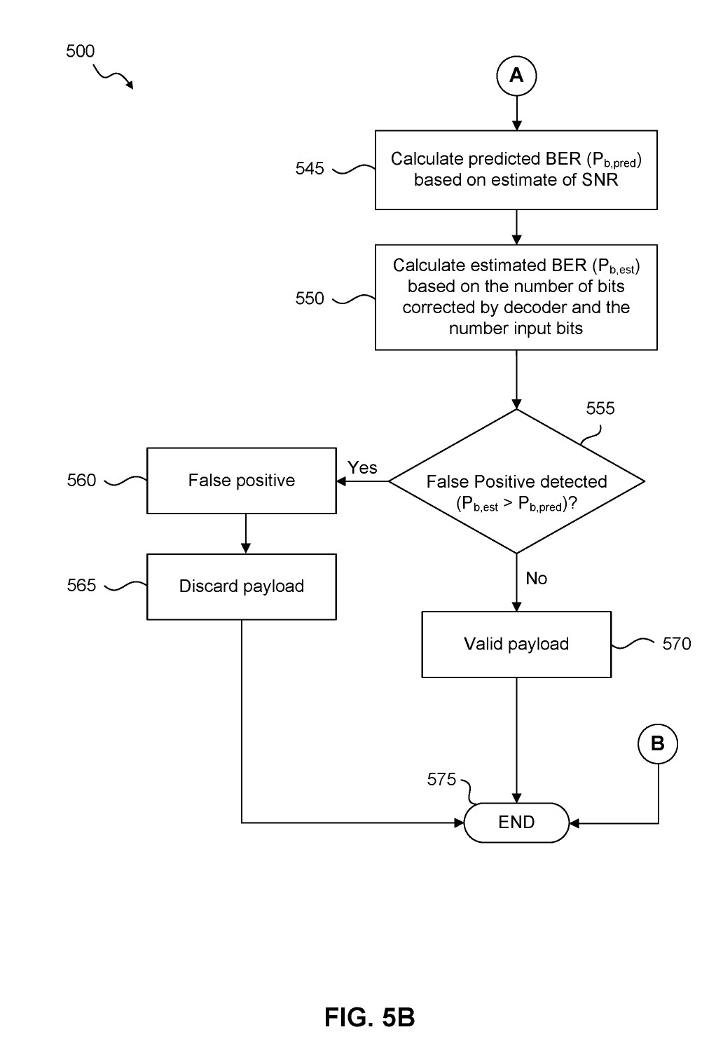

Turning to FIGS. 5A and 5B, a flowchart of false positive detection method 500 according to an exemplary aspect of the present disclosure is illustrated. The flowchart is described with continued reference to FIGS. 1-4. The steps of the method are not limited to the order described below, and the various steps may be performed in a different order. Further, two or more steps of the method may be performed simultaneously with each other.

The method of method 500 begins at step 505 and transitions to step 510, where a received signal is demodulated. In an exemplary aspect, the demodulator 410 demodulates a RF signal received via antenna 435 to generate a demodulated signal. The demodulated signal is then provided to the de-rate matching circuit 420.

After step 510, the method 500 transitions to step 515, where the demodulated signal is de-rate matched to generate a de-rate matched signal. In an exemplary aspect, the de-rate matching circuit 420 performs one or more de-rate matching operations on the demodulated signal to generate a de-rate matched signal. The de-rate matching circuit 420 then provides the de-rate matched signal to the decoder 425.

After step 515, the method 500 transitions to step 520, where the de-rate matched signal is decoded. In an exemplary aspect, the decoder 425 decodes the de-rate matched signal to generate a decoded signal. The decoded signal can then be provided to the controller 445, and more specifically, to the error detector 450.

After step 520, the method 500 transitions to step 525, where the decoded signal is checked to determine whether the decoded signal contains one or more errors. In an exemplary aspect, the error detector 450 can be configured to perform one or more error detection operations to detect one or more errors of the decoded signal. The error detector 450 can be configured to detect one or more errors of the received signal based on an error detection code, such as a cyclic redundancy check (CRC) code.

For example, the error detector 450 can detect one or more bit errors of the decoded signal received from the decoder 425, and can be configured to use one or more error detection methodologies and/or algorithms to detect errors. In an exemplary aspect, the error detector 450 can be configured to use cyclic redundancy check (CRC) code, but is not limited thereto.

In operation, the error detector 450 can be configured to check the integrity/validity of the payload bits of the decoded signal based on the error detection code bits (e.g., the CRC code). The error detector 450 can generate an output that includes the payload data and/or a value indicative of whether the payload data is valid. The output of the error detector 450 can be provided to the false positive detector 460.

If an error is detected in the decoded signal (YES at step 525), the method 500 transitions to step 530, where the payload of the decoded signal is determined to be invalid. After step 530, the method 500 transitions to step 535, where the invalid payload is discarded. In an exemplary aspect, the error detector 450 is configured to determine that the payload is invalid and to discard payload data determined to be invalid. After step 535, the method transitions to step 575, where the method 500 ends. The method 500 can be repeated for one or more signal subsequently received by, for example, the mobile device 440.

If no errors are detected in the decoded signal (NO at step 525), the method 500 transitions to step 545, where a predicted bit-error rate (BER) is calculated. In an exemplary aspect, the predicted BER is calculated based on an estimate of the signal-to-noise ratio (SNR) of the received RF signal. In an exemplary aspect, the predicted BER is calculated based the estimate of the SNR, an SNR margin, one or more encoding parameters (e.g., E and/or dciLength), and/or one or more rate-matching parameters (e.g., F_{allocation} and/or L). In an exemplary aspect, the false positive detector 460 can be configured calculate the predicted BER (P_{b,pred}) based on the SNR of the RF signal received by the transceiver 405, an SNR margin, one or more encoding parameters (e.g., E and/or dciLength), and/or one or more rate-matching parameters (e.g., F_{allocation} and/or L). In this example, the demodulator 410 can be configured to estimate the SNR and provide the estimated SNR to the false positive detector 460. The demodulator 410 can be configured to estimate the SNR based on one or more pilot and/or reference signals within the received RF signal.

After step 545, the method 500 transitions to step 550, where an estimated BER (P_{b,est}) is calculated. In an exemplary aspect, the estimated BER is calculated based on the number of bits corrected (B_{C}) by the decoder 425 and the number of input bits (Bᵢₙₚᵤₜ) (i.e., bits of the coded signal) of the decoder 425.

In an exemplary aspect, the false positive detector 460 can be configured calculate the estimated BER (P_{b,est}) based on the number of bits corrected (B_{C}) and the number of input bits (Bᵢₙₚᵤₜ). The decoder 425 can be configured to provide the number of bits corrected (B_{C}) and/or the number of input bits (Bᵢₙₚᵤₜ) to the false positive detector 460. In an alternative aspect, the decoder 425 can be configured calculate the estimated BER based on the number of bits corrected (B_{C}) and the number of input bits (Bᵢₙₚᵤₜ), and provide the estimated BER to the false positive detector 460.

After step 550, the method 500 transitions to step 555 where it is determined whether a false positive has occurred. For example, the decoded signal having been checked for errors by the error detector 450 and determined to be error free by the error detector 450 may nonetheless contain errors. In an exemplary aspect, the false positive detector 460 is configured to detect one or more false positives of the signals received from the error detector 450 that have been passed error detection (i.e., determined to have valid payloads by the error detector 450).

In an exemplary aspect, the occurrence of a false positive (FP) based on the predicted BER (P_{b,pred}) and the estimated BER (P_{b,est}) is determined.

If the estimated BER (P_{b,est}) is greater than the predicted BER (P_{b,pred}) (YES at step 555), the method 500 transitions to step 560 where it is determined that a false positive has occurred. After step 560, the method 500 transitions to step 565, where the false positive determined payload is discarded. In an exemplary aspect, the false positive detector 460 is configured to determine that a false positive has occurred and to discard payload data. After step 565, the method transitions to step 575, where the method 500 ends. The method 500 can be repeated for one or more signal subsequently received by, for example, the mobile device 440.

Otherwise (NO at step 555), the method 500 transitions to step 570 where it is determined that a false positive has not occurred and that the payload data is valid. After step 570, the method transitions to step 575, where the method 500 ends. The method 500 can be repeated for one or more signal subsequently received by, for example, the mobile device 440.

### EXAMPLES

Example 1 is a communication device operable to receive an encoded signal, comprising: an error detector configured to detect an error of a decoded signal generated from the encoded signal; and a false positive detector configured to determine a false positive of the decoded signal having passed error detection by the error detector based on an estimated bit-error rate (BER) of the encoded signal and a predicted BER of the encoded signal.

In Example 2, the subject matter of Example 1, wherein the false positive detector is further configured to calculate the estimated BER based on: a number of bits corrected through decoding of the encoded signal that generates the decoded signal; and a number of bits of the encoded signal.

In Example 3, the subject matter of Example 2, wherein the false positive detector is configured to calculate the estimated BER based on a ratio of the number of bits corrected and the number of bits of the encoded signal.

In Example 4, the subject matter of Example 3, wherein the false positive detector is further configured to calculate the predicted BER based on a signal-to-noise ratio (SNR) of the encoded signal.

In Example 5, the subject matter of Example 1, wherein the false positive detector is further configured to calculate the predicted BER based on a signal-to-noise ratio (SNR) of the encoded signal.

In Example 6, the subject matter of Example 5, wherein the false positive detector is configured to calculate the predicted BER based on a tail probability of the SNR of the encoded signal and a repetition factor.

In Example 7, the subject matter of Example 1, wherein the false positive detector is configured to determine the false positive if the estimated BER is greater than the predicted BER.

Example 8 is a communication device operable to receive an encoded signal, comprising: a transceiver configured to generate a decoded signal from the received encoded signal; and a controller that includes: an error detector configured to detect an error of a decoded signal generated from the encoded signal; and a false positive detector configured to determine a false positive of the decoded signal having passed error detection by the error detector based on an estimated bit-error rate (BER) of the encoded signal and a predicted BER of the encoded signal.

In Example 9, the subject matter of Example 8, wherein the transceiver comprises: a demodulator that is configured to demodulate the encoded signal to generate a demodulated signal; and a decoder configured to decode the demodulated signal to generate the decoded signal.

In Example 10, the subject matter of Example 9, wherein: the decoder is further configured to provide, to the false positive detector, a number of bits corrected through decoding of the demodulated signal and a number of bits of the demodulated signal; and the false positive detector is further configured to calculate the estimated BER based on the number of corrected bits and the number of bits of the encoded signal.

In Example 11, the subject matter of Example 10, wherein the false positive detector is configured to calculate the estimated BER based on a ratio of the number of bits corrected and the number of bits of the encoded signal.

In Example 12, the subject matter of Example 10, wherein the false positive detector is further configured to calculate the predicted BER based on a signal-to-noise ratio (SNR) of the encoded signal.

In Example 13, the subject matter of Example 12, wherein the false positive detector is further configured to calculate the predicted BER based on a SNR margin factor, wherein the SNR margin factor depends on a channel quality.

In Example 14, the subject matter of Example 9, wherein: the demodulator further configured to determine a signal-to-noise ratio (SNR) of the encoded signal to provide the SNR to the false positive detector; and the false positive detector is further configured to calculate the predicted BER based on the SNR of the encoded signal.

In Example 15, the subject matter of Example 14, wherein the false positive detector is configured to calculate the predicted BER based on a tail probability of the SNR of the encoded signal and a repetition factor.

In Example 16, the subject matter of Example 15, wherein the repetition factor is based on at least one of: an allocation factor of a communication protocol associated with the received encoded signal; an aggregation level; and a payload size of the received encoded signal.

In Example 17, the subject matter of Example 8, wherein the false positive detector is configured to determine the false positive if the estimated BER is greater than the predicted BER.

Example 18 is a false positive detection method, comprising: detecting an error of a decoded signal generated from a encoded signal; calculate an estimated bit-error rate (BER) of the encoded signal; calculate a predicted BER of the encoded signal; and determine a false positive of the error detection passing of the decoded signal based on the calculated estimated BER and the calculated predicted BER.

In Example 19, the subject matter of Example 18, wherein the calculation of the estimated BER is based on a ratio of: a number of bits corrected through decoding of the encoded signal that generates the decoded signal; and a number of bits of the encoded signal.

In Example 20, the subject matter of Example 18, wherein the calculation of the predicted BER is based on a signal-to-noise ratio (SNR) of the encoded signal.

In Example 21, the subject matter of Example 20, wherein the calculation of the predicted BER is based on a SNR margin factor, wherein the SNR margin factor depends on a channel quality.

In Example 22, the subject matter of Example 18, wherein the calculation of the predicted BER is based on a tail probability of the SNR of the encoded signal and a repetition factor.

Example 23 is a communication device operable to receive an encoded signal, comprising: error detecting means for detecting an error of a decoded signal generated from the encoded signal; and false positive detecting means for determining a false positive of the decoded signal having passed error detection by the error detector based on an estimated bit-error rate (BER) of the encoded signal and a predicted BER of the encoded signal.

In Example 24, the subject matter of Example 23, wherein the false positive detecting means calculates the estimated BER based on: a number of bits corrected through decoding of the encoded signal that generates the decoded signal; and a number of bits of the encoded signal.

In Example 25, the subject matter of Example 24, wherein the false positive detecting means calculates the estimated BER based on a ratio of the number of bits corrected and the number of bits of the encoded signal.

In Example 26, the subject matter of Example 24, wherein the false positive detecting means calculates the predicted BER based on a signal-to-noise ratio (SNR) of the encoded signal.

In Example 27, the subject matter of any of Examples 23-26, wherein the false positive detecting means calculates the predicted BER based on a signal-to-noise ratio (SNR) of the encoded signal.

In Example 28, the subject matter of Example 27, wherein the false positive detecting means calculates the predicted BER based on a tail probability of the SNR of the encoded signal and a repetition factor.

In Example 29, the subject matter of any of Examples 23-28, wherein the false positive detecting means determines the false positive if the estimated BER is greater than the predicted BER.

Example 30 is a false positive detection method, comprising: detecting an error of a decoded signal generated from a encoded signal; calculate an estimated bit-error rate (BER) of the encoded signal; calculate a predicted BER of the encoded signal; and determine a false positive of the error detection passing of the decoded signal based on the calculated estimated BER and the calculated predicted BER.

In Example 31, the subject matter of Example 30, wherein the calculation of the estimated BER is based on a ratio of: a number of bits corrected through decoding of the encoded signal that generates the decoded signal; and a number of bits of the encoded signal.

In Example 32, the subject matter of any of Examples 30-31, wherein the calculation of the predicted BER is based on a signal-to-noise ratio (SNR) of the encoded signal.

In Example 33, the subject matter of Example 32, wherein the calculation of the predicted BER is based on a SNR margin factor, wherein the SNR margin factor depends on a channel quality.

In Example 34, the subject matter of any of Examples 30-33, wherein the calculation of the predicted BER is based on a tail probability of the SNR of the encoded signal and a repetition factor.

Example 35 is a computer program product embodied on a computer-readable medium comprising program instructions, when executed, causes a machine to perform the method of any of Examples 30-34.

In Example 36, the subject matter of any of Examples 1-4, wherein the false positive detector is further configured to calculate the predicted BER based on a signal-to-noise ratio (SNR) of the encoded signal.

In Example 37, the subject matter of Example 36, wherein the false positive detector is configured to calculate the predicted BER based on a tail probability of the SNR of the encoded signal and a repetition factor.

In example 38, the subject matter of any of Examples 1-4, wherein the false positive detector is configured to determine the false positive if the estimated BER is greater than the predicted BER.

Example 39 is a computer program product embodied on a computer-readable medium comprising program instructions, when executed, causes a machine to perform the method of any of Examples 18-22.

Example 40 is an apparatus comprising means to perform the method as claimed in any of examples 18-22.

Example 41 is an apparatus substantially as shown and described.

Example 42 is a method substantially as shown and described.

### CONCLUSION

The aforementioned description of the specific aspects will so fully reveal the general nature of the disclosure that others can, by applying knowledge within the skill of the art, readily modify and/or adapt for various applications such specific aspects, without undue experimentation, and without departing from the general concept of the present disclosure. Therefore, such adaptations and modifications are intended to be within the meaning and range of equivalents of the disclosed aspects, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

References in the specification to “one aspect,” “an aspect,” “an exemplary aspect,” etc., indicate that the aspect described may include a particular feature, structure, or characteristic, but every aspect may not necessarily include the particular feature, structure, or characteristic. Moreover, such phrases are not necessarily referring to the same aspect. Further, when a particular feature, structure, or characteristic is described in connection with an aspect, it is submitted that it is within the knowledge of one skilled in the art to affect such feature, structure, or characteristic in connection with other aspects whether or not explicitly described.

The exemplary aspects described herein are provided for illustrative purposes, and are not limiting. Other exemplary aspects are possible, and modifications may be made to the exemplary aspects. Therefore, the specification is not meant to limit the disclosure. Rather, the scope of the disclosure is defined only in accordance with the following claims and their equivalents.

Aspects may be implemented in hardware (e.g., circuits), firmware, software, or any combination thereof. Aspects may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general purpose computer.

For the purposes of this discussion, the term “processor circuitry” shall be understood to be circuit(s), processor(s), logic, or a combination thereof. For example, a circuit can include an analog circuit, a digital circuit, state machine logic, other structural electronic hardware, or a combination thereof. A processor can include a microprocessor, a digital signal processor (DSP), or other hardware processor. The processor can be “hard-coded” with instructions to perform corresponding function(s) according to aspects described herein. Alternatively, the processor can access an internal and/or external memory to retrieve instructions stored in the memory, which when executed by the processor, perform the corresponding function(s) associated with the processor, and/or one or more functions and/or operations related to the operation of a component having the processor included therein.

In one or more of the exemplary aspects described herein, processor circuitry can include memory that stores data and/or instructions. The memory can be any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

As will be apparent to a person of ordinary skill in the art based on the teachings herein, exemplary aspects are not limited to Long-Term Evolution (LTE) and can be applied to other cellular communication standards, including (but not limited to), Evolved High-Speed Packet Access (HSPA+), Wideband Code Division Multiple Access (W-CDMA), CDMA2000, Time Division-Synchronous Code Division Multiple Access (TD-SCDMA), Global System for Mobile Communications (GSM), General Packet Radio Service (GPRS), Enhanced Data Rates for GSM Evolution (EDGE), and Worldwide Interoperability for Microwave Access (WiMAX) (Institute of Electrical and Electronics Engineers (IEEE) 802.16) to provide some examples. Further, exemplary aspects are not limited to cellular communication networks and can be used or implemented in other kinds of wireless communication access networks, including (but not limited to) one or more IEEE 802.11 protocols, Bluetooth, Near-field Communication (NFC) (ISO/IEC 18092), ZigBee (IEEE 802.15.4), and/or Radio-frequency identification (RFID), to provide some examples. Further, exemplary aspects are not limited to the above wireless networks and can be used or implemented in one or more wired networks using one or more well-known wired specifications and/or protocols.

What is claimed is:

1. A communication device operable to receive an encoded signal, comprising:
an error detector configured to detect an error of a decoded signal generated from the encoded signal; and
a false positive detector configured to determine a false positive of the decoded signal having passed error detection by the error detector based on an estimated bit-error rate (BER) of the encoded signal and a predicted BER of the encoded signal.

2. The communication device of claim 1, wherein the false positive detector is further configured to calculate the estimated BER based on:
a number of bits corrected through decoding of the encoded signal that generates the decoded signal; and
a number of bits of the encoded signal.

3. The communication device of claim 2, wherein the false positive detector is configured to calculate the estimated BER based on a ratio of the number of bits corrected and the number of bits of the encoded signal.

4. The communication device of claim 2, wherein the false positive detector is further configured to calculate the predicted BER based on a signal-to-noise ratio (SNR) of the encoded signal.

5. The communication device of claim 1, wherein the false positive detector is further configured to calculate the predicted BER based on a signal-to-noise ratio (SNR) of the encoded signal.

6. The communication device of claim 5, wherein the false positive detector is configured to calculate the predicted BER based on a tail probability of the SNR of the encoded signal and a repetition factor.

7. The communication device of claim 1, wherein the false positive detector is configured to determine the false positive if the estimated BER is greater than the predicted BER.

8. A communication device operable to receive an encoded signal, comprising:
a transceiver configured to generate a decoded signal from the received encoded signal; and
a controller that includes:
an error detector configured to detect an error of a decoded signal generated from the encoded signal; and
a false positive detector configured to determine a false positive of the decoded signal having passed error detection by the error detector based on an estimated bit-error rate (BER) of the encoded signal and a predicted BER of the encoded signal.

9. The communication device of claim 8, wherein the transceiver comprises:
a demodulator that is configured to demodulate the encoded signal to generate a demodulated signal; and
a decoder configured to decode the demodulated signal to generate the decoded signal.

10. The communication device of claim 9, wherein:
the decoder is further configured to provide, to the false positive detector, a number of bits corrected through decoding of the demodulated signal and a number of bits of the demodulated signal; and
the false positive detector is further configured to calculate the estimated BER based on the number of corrected bits and the number of bits of the encoded signal.

11. The communication device of claim 10, wherein the false positive detector is configured to calculate the estimated BER based on a ratio of the number of bits corrected and the number of bits of the encoded signal.

12. The communication device of claim 10, wherein the false positive detector is further configured to calculate the predicted BER based on a signal-to-noise ratio (SNR) of the encoded signal.

13. The communication device of claim 12, wherein the false positive detector is further configured to calculate the predicted BER based on a SNR margin factor, wherein the SNR margin factor depends on a channel quality.

14. The communication device of claim 9, wherein:
the demodulator further configured to determine a signal-to-noise ratio (SNR) of the encoded signal to provide the SNR to the false positive detector; and
the false positive detector is further configured to calculate the predicted BER based on the SNR of the encoded signal.

15. The communication device of claim 14, wherein the false positive detector is configured to calculate the predicted BER based on a tail probability of the SNR of the encoded signal and a repetition factor.

16. The communication device of claim 15, wherein the repetition factor is based on at least one of:
an allocation factor of a communication protocol associated with the received encoded signal;
an aggregation level; and
a payload size of the received encoded signal.

17. The communication device of claim 8, wherein the false positive detector is configured to determine the false positive if the estimated BER is greater than the predicted BER.

18. A false positive detection method, comprising:
detecting an error of a decoded signal generated from a encoded signal;
calculate an estimated bit-error rate (BER) of the encoded signal;
calculate a predicted BER of the encoded signal; and
determine a false positive of the error detection passing of the decoded signal based on the calculated estimated BER and the calculated predicted BER.

19. The false positive detection method of claim 18, wherein the calculation of the estimated BER is based on a ratio of:
a number of bits corrected through decoding of the encoded signal that generates the decoded signal; and
a number of bits of the encoded signal.

20. The false positive detection method of claim 18, wherein the calculation of the predicted BER is based on a signal-to-noise ratio (SNR) of the encoded signal.

21. The false positive detection method of claim 20, wherein the calculation of the predicted BER is based on a SNR margin factor, wherein the SNR margin factor depends on a channel quality.

22. The false positive detection method of claim 18, wherein the calculation of the predicted BER is based on a tail probability of the SNR of the encoded signal and a repetition factor.
